(19) United States
(12) Patent Application Publication
(10) Pub. No.: US 2026/0371779 A1
(43) Pub. Date: Nov. 19, 2026

(54) III-V SEMICONDUCTOR STRUCTURE AND MANUFACTURING METHOD

(71) Applicant: TURUN YLIOPISTO, Turun yliopisto (FI)

(72) Inventors: Zahra JAHANSHAH RAD, Turku (FI); Pekka LAUKKANEN, Turku (FI); Juha-Pekka LEHTIÖ, Turku (FI); Marko PUNKKINEN, Turku (FI); Kalevi KOKKO, Turku (FI)

(21) Appl. No.: 19/120,998

(22) PCT Filed: Oct. 13, 2023
(86) PCT No.: PCT/FI2023/050587

§ 371 Date: Apr. 14, 2025

(30) Foreign Application Priority Data
Oct. 14, 2022 (FI) 20225935

(51) Int. Cl. H10F 77/169; H10F 71/00; H10F 77/124; H10F 77/42

(52) U.S. Cl. CPC H10F 77/169; H10F 71/1276; H10F 77/124; H10F 77/42

(57) ABSTRACT

A III-V compound semiconductor structure comprising a crystalline III-V compound semiconductor substrate layer (110); the substrate layer (110) having an outer surface (111) and an oxide layer (120) of oxide(s) of the III-V semiconductor substrate layer on the outer surface, the oxide layer comprising a plurality of crystalline nanoparticles (121) having a maximum diameter in the range of 0.2 nm to 200 nm, for example, 0.5 nm to 150 nm, for example, 1 nm to 100 nm, for example, 2 nm to 80 nm, for example, 3 nm to 50 nm.

### FIELD OF TECHNOLOGY

This disclosure concerns semiconductor technology, in particular, III-V semiconductor structures and methods for forming the same. At least some aspects of the disclosure relate to structures suitable for anti-reflection purposes.

### BACKGROUND

Properties of III-V compound semiconductor materials makes them useful for optoelectronic applications. For example, gallium arsenide has a direct bandgap, which allows it to absorb light effectively, making it a useful material for various photovoltaic devices. III-V compound semiconductors are also widely used in light emitting devices such as light emitting diodes LEDs and lasers. Another example of versatile III-V compound semiconductor materials is gallium antimony GaSb.

The efficiency of photovoltaic devices, such as solar cells and photodetectors, can be improved by applying an anti-reflection coating on the surface(s) of the structure. Anti-reflection AR coatings may be incorporated also in light emitting devices such as light emitting diodes LEDs, and lasers, such as vertical cavity surface emitting lasers VCSELs. In addition to or instead of the anti-reflection function, also passivation of active surfaces of the device structure participating in light reception or emission by an appropriate coating may be useful. Passivation may also be needed to enhance the electrical properties of various structures. The same coating formed, for example, oxide(s) of the compound semiconductor material(s), may serve for both functions.

One method to produce III-V compound semiconductor anti-reflection coating on a semiconductor is to fabricate crystalline particles in micrometer scale on the surface. These nanostructures are able to trap part of the light that is incident on the material, therefore preventing some of the photons from reflecting. Known are also various multi-layered AR coatings.

With regard to passivation function, a layer of oxide(s) of the semiconductor material(s) on a device structure may reduce the loss of charge carriers on the active area of the device such as a solar cell, LED, or some other light emitting or receiving device, thereby increasing the efficiency thereof.

However, existing methods to produce anti-reflection and/or passivation structures on III-V semiconductor materials are complex, expensive, and their scalability may be incomplete. In addition, the wavelength bandwidth of the decreased reflection is relatively narrow in structures produced by at least some of these methods.

Therefore, new solutions for facilitating implementation of efficient, and preferably broadband AR coatings for III-V compound semiconductor devices are needed.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

According to a first aspect, a III-V compound semiconductor structure suitable for serving as an anti-reflection structure is disclosed.

The III-V compound semiconductor structure comprises a crystalline III-V compound semiconductor substrate layer.

The group III element comprises gallium Ga and/or indium In, and the group V element is arsenide As, phosphorus P, or antimony Sb. Possible materials of the crystalline III-V compound semiconductor substrate layer thereby comprise, for example, GaAs, InGaAs, GaSb, and InP.

The semiconductor structure has an outer surface and comprises an oxide layer of one or more oxide(s) of the III-V semiconductor substrate layer on the outer surface.

An “outer surface” may refer to a surface limiting the actual semiconductor structure in question. Such surface may be a top or a bottom surface of a layer-formed semiconductor structure. It may also refer to a side surface of a three-dimensional structure, the side surface being inclined, for example, perpendicularly, relative to the direction of extension of the layer(s) of a layer-formed structure. One example is the side surface of a mesa structure formed, for example by etching, in a layered semiconductor structure. The “outer” surface does not mean that the surface should be free, i.e. without being covered by any further layer(s) or structure(s). Instead, there may be one or more layer(s) or structure(s) lying on the outer surface of the semiconductor structure.

The oxide layer comprises a plurality of crystalline nanoparticles having a maximum diameter in the range of 0.2 nm to 200 nm, for example, 0.5 nm to 150 nm, for example, 1 nm to 100 nm, for example, 2 nm to 80 nm, for example, 3 nm to 50 nm. In some embodiments, the maximum diameter may be in the range of 0.2 to 400 nm, for example, 4 nm to 40 nm or 5 nm to 30 nm. In some embodiments, the maximum diameter may be less than or equal to 10 nm.

In one embodiment, the outer surface is porous, and has a top part and a plurality of cavities extending from the level of the top part into the substrate layer, the cross-section of a cavity at the level of the top part defining a sub-micron pore opening. In this embodiment, the substrate layer may comprise, for example, GaAs.

According to a second aspect, a method is disclosed for forming a III-V compound semiconductor structure suitable for serving as an anti-reflection structure.

The method comprises providing a crystalline III-V compound semiconductor substrate layer, wherein the group Ill element comprises gallium Ga and/or indium In, and the group V element is arsenide As, phosphorus P, or antimony Sb, the substrate layer having an outer surface;
subjecting the outer surface to liquid hot hydrogen peroxide H₂O₂, HHP, at a temperature of the HHP in the range of 60 °C to 99 °C, for example, 65 °C to 95 °C, for example, 70 °C. to 90 °C, for example, about 80 °C, for an HHP treatment period of at least 2 minutes, at least 5 minutes, at least 10 minutes, at least 15 minutes, at least 30 minutes, or at least 60 minutes; and
then subjecting the outer surface to liquid hot water H₂O, HW, at a temperature of the HW in the range of 60 °C to 99 °C, for example, 65 °C to 95 °C, for example, 70 °C to 90 °C, for example, about 80 °C, for a HW treatment period of 2 minutes, at least 5 minutes, at least 10 minutes, at least 15 minutes, at least 30 minutes, or at least 60 minutes.

Further embodiments of the above aspects may be implemented within the scope of the claims.

### BRIEF DESCRIPTION OF THE DRAWINGS

The present disclosure will be better understood from the following detailed description read in light of the accompanying drawings, wherein:

FIG. 1 shows a part of a III-V compound semiconductor structure in different stages of its manufacturing process;

FIG. 2 shows a top view of the semiconductor structure of FIG. 1;

FIG. 3 shows a scanning electron microscope SEM image of a GaAs semiconductor substrate layer with a porous outer surface;

FIG. 4 shows a scanning electron microscope SEM image of a GaAs semiconductor structure with a substrate layer and an oxide layer thereon;

FIGS. 5a and 5b show a scanning electron microscope SEM image and an atomic force microscope AFM image, respectively, of GaSb semiconductor structures with a substrate layer and an oxide layer thereon;

FIGS. 6a, 6b, and 9 show graphs of reflectance measurements of III-V compound semiconductor structures;

FIG. 7 shows a III-V compound semiconductor device with an antireflection structure thereon;

FIG. 8 shows a flow chart of a method for forming a III-V compound semiconductor structure;

FIG. 10 shows a solar cell structure; and

FIG. 11 shows photoluminescence and reflectance measurements of the solar cell structure of FIG. 10.

Unless specifically stated to the contrary, any drawing of the aforementioned drawings may be schematic and drawn not to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

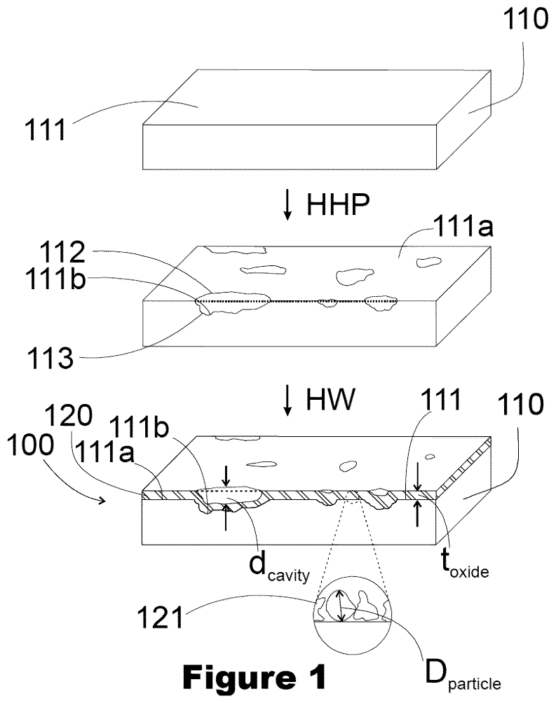

The uppermost illustration of FIG. 1 shows a crystalline III-V compound semiconductor substrate layer 110.

“III-V compound semiconductor” refers to a semiconductor material of an alloy containing elements of groups III and V in the periodic table. The group III element may be, for example, gallium Ga or indium In. Alternatively, the III-V compound semiconductor may comprise both Ga and In as group Ill elements. The group V element may be, for example, arsenic As or phosphorus P, or antimony Sb. Thus, the compound semiconductor material may be, for example, gallium arsenide GaAs, indium phosphide InP, indium gallium phosphide InGaP, indium gallium arsenide InGaAs, or gallium antimony GaSb.

“Crystalline” layer or element of a material may refer to constituents, such as atomic nuclei, of said material forming an ordered, three-dimensional crystal lattice.

A “layer” refers to a structural entity which may extend substantially along, or parallel to, a fictional base surface or plane (not illustrated in the FIGs.), and have a thickness in a direction perpendicular to said surface or plane substantially smaller than the dimensions of the layer along or parallel to said surface. Such base surface or plane may be planar or curved.

A “substrate” layer refers to the substrate layer capable of serving as a substrate in the sense that further layer(s) or element(s) may be formed on or attached to the substrate layer.

The substrate layer 110 has an outer surface 111. “Outer” refers in this example to that surface being defined to form the “uppermost” main surface of the substrate layer when observed in a fictitious coordinate system fixed to the semiconductor structure with the horizontal directions defined by the fictitious base surface or plane, and the upwards/downwards directions directed along the thickness direction of the substrate layer. That surface might therefore be called also a top surface. Further, that surface might also be called a deposition surface, “deposition” referring to a possibility to deposit, or to have deposited, some material on the deposition surface.

In other embodiments or examples, an outer surface of a semiconductor structure may comprise a bottom surface of a substrate layer. In yet other embodiments or examples, an outer surface may comprise a side surface of a semiconductor substrate layer, or a side surface of a three-dimensional structure formed in a substrate layer. Such three-dimensional structure may be, for example, a mesa structure formed in a semiconductor substrate layer, for example, by etching.

Referring to the drawings of FIG. 1, the outer surface 111 may also be considered an outer surface or an upper surface of the substrate layer, referring to it being faced “upwards” in the coordinates of the illustration of FIG. 1.

As marked adjacent to the arrow between the uppermost and the middlemost drawings of FIG. 1, the middlemost drawing illustrates the substrate layer 110 after exposure of the outer surface to hot hydrogen peroxide H₂O₂, hereinafter referred to as “HHP”.

The HHP subjection or treatment may be carried out in accordance with the below disclosure of the method aspects with reference to FIG. 8.

In the example of FIG. 1, result of the HHP treatment, the outer surface 111 of the substrate layer 110 is porous, comprising a top part 111a and a plurality of cavities 111b which extend from the level of the top part into the substrate layer.

The “level” of the top part 111a refers to a fictitious level substantially along which or parallel to which the top part of the outer surface lies. It hereby defines, at each “horizontal” location, the substantial position of the top part 111, or the extension of the top part where it is missing, in the thickness direction of the substrate layer 110 and the entire semiconductor structure 100. Whereas that level may be planar, the actual top part 111a itself may have some roughness or other type or topology such that the position thereof in the thickness direction of the substrate layer has some fluctuation around the level. Thereby, the “level of the top part” may refer to a plane located in the thickness direction of the semiconductor layer at the average thickness direction position of the top part 111a of the outer layer 111.

Each cavity 111b thereby forms a “pore” in the outer surface.

In the example of FIG. 1, the top part 111a is substantially planar. In other embodiments, it may be curved or have some other three-dimensional shape. Then, the depth of a cavity may be defined as measured perpendicularly relative to the tangent of the top part at the location of the cavity.

On the other hand, the cross-section of each cavity 111b at the level of the top part 111a of the outer surface defines a sub-micron pore opening 112. The top part 111a of the outer surface is thus missing at the pore opening.

At least some of the pore openings 112 may be substantially elongated. An elongated pore opening may be substantially straight, i.e. have one single longitudinal direction. An elongated pore opening may alternatively be curved or wavy. Any elongated pore opening may have a width varying along the longitudinal direction(s) of the pore opening.

At least some of the pore openings 112 may have a non-elongated shape, such as substantially roundish or polygonal shape. Such pore openings may have deviations from the basic shape of e.g. a circle or a polygon such as a rectangular. Thus, the actual outline of a pore opening may follow such basic shape only approximately.

There are cavities 111b, and thus pore openings 112, of different sizes and shapes at the outer surface 111.

“Sub-micron” relates to the dimensions of the pore openings and refer to the maximum diameter Dₚₒᵣₑ of each pore opening 112 of the plurality of the sub-pore pore openings lying in the sub-micron range, i.e. less than or equal to 1 micron, thus 1 μm.

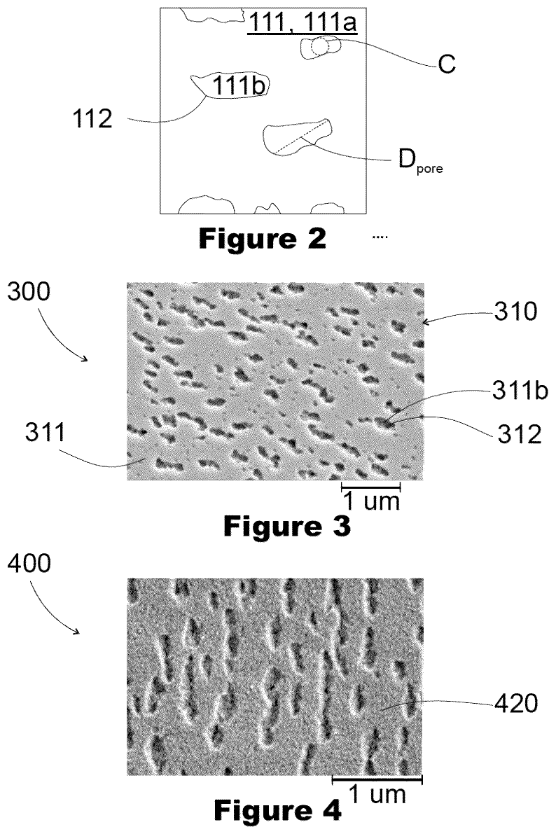

“Maximum diameter” Dₚₒᵣₑ of a pore opening refers to a longest distance, measured along a straight line, between two points of the pore opening. The maximum diameter of one pore opening is marked in the drawing of FIG. 2.

In addition to the plurality of sub-micron pore openings with maximum diameter as discussed above, an outer surface may comprise also larger pore openings having maximum diameter equal to or higher than 1 μm.

The cavities have a maximum cavity depth d_{cavity}, measured from the level of the top part 111a. The maximum cavity depth of a cavity 111b at the location may lie, for example, between 5 nm and the maximum diameter Dₚₒᵣₑ of the pore opening 112 of that cavity.

The dimensions of the pore openings are discussed further below with reference to FIG. 2.

The lowermost drawing of FIG. 1 illustrates a semiconductor structure 100 comprising the semiconductor substrate layer 110.

The III-V semiconductor structure 100 illustrated in FIG. 1 may form an integral or inseparable part of a complete, operable semiconductor device. Alternatively, it may be a discrete or stand-alone structure possibly attached to or formed on a semiconductor device.

In the case of the III-V semiconductor being attached to or formed on, or forming a part of another structure or layer of e.g. a complete semiconductor device, the underlying structure or layer may be of the same or different material as the III-V semiconductor layer. Especially, the underlying structure or layer may be of different III-V semiconductor material. For example, a III-V semiconductor structure with a substrate layer of GaAs may lie on an underlying structure or layer of InP.

As marked adjacent to the arrow between the middlemost and the lowermost drawings of FIG. 1, the lowermost drawing illustrates the semiconductor structure 110 after subjection of the porous outer surface 111a, 111b to hot water H₂O, HW. It may be preferable to use deionized water. In some embodiments, distilled water may be used.

The HW subjection or treatment may be carried out in accordance with the below disclosure the method aspects with reference to FIG. 8.

In result of the HW treatment, the semiconductor structure comprises an oxide layer 120 on the outer surface 111.

The oxide layer 120 is formed all over the outer surface 111, i.e. both on the top part 111a and on the cavities 111b.

The oxide layer may comprise oxide of at least one of the III-V compound semiconductor elements. For example, in the case of GaAs as the III-V semiconductor element, the oxide layer may comprise at least gallium oxide GaOₓ, and possibly also arsenic oxide AsOₓ. “X” in those molecular formula denotes that the oxide layer may comprise non-stochiometric oxide composition(s) instead of, or in addition to, the stoichiometric composition(s) Ga₂O₃, As₂O₄.

In addition to, or instead of, oxide(s) of the III-V compound semiconductor elements, the oxide layer 120 may comprise oxide hydroxide of at least one of the III-V compound semiconductor elements. For example, in the case of Ga as the group III element and As as the group IV element, the oxide layer may comprise gallium oxide hydroxide GaHO₂.

The oxide layer 120 comprises, and may be substantially formed by, a plurality of crystalline nanoparticles 121.

“Nanoparticle” refers to a particle with its maximum diameter in the nanometer range, i.e. substantially below 1 μm, for example, less than or equal to 500 nm.

“Maximum diameter” D_{particle} of a nanoparticle refers to a longest distance, measured along a straight line, be-tween two points of the three-dimensional nanoparticle. The maximum diameter of one nanoparticle is marked in the lowermost drawing of FIG. 1.

The nanoparticles 121 of the oxide layer 120 may have different sizes. At least a part of the plurality of nanoparticles, possibly all of them, may have a maximum diameter in the range of 0.2 nm to 200 nm, for example, 0.5 nm to 150 nm, for example, 1 nm to 100 nm, for example, 2 nm to 80 nm, for example, 3 nm to 50 nm.

Maximum diameter of the at least part of the nanoparticles lying in a specific range may refer to those nanoparticles comprising nanoparticles of different sizes, thus with different maximum diameters within the specific range. Alternatively, it may refer to those nanoparticles comprising substantially equally dimensioned nanoparticles having their maximum diameters within a narrower sub-range of the specific range, the sub-range having a center value, for example, of 1, 2, 5, 10, 20, 50, or 80 nm.

In addition to the plurality of nanoparticles with dimensions as discussed above, the oxide layer may comprise also larger and/or smaller nanoparticles.

The thickness of the oxide layer t_{oxide} layer may depend on the size range of the nanoparticles. The thickness may lie, for example, in the range of about of 1 to 200 nm, for example, 2 to 150 nm, for example, 3 to 100 nm, for example, 5 to 80 nm. It may alternatively lie in the range of 0.2 nm to 400 nm or 0.2 to 200 nm, for example, 0.5 nm to 150 nm, for example, 1 nm to 100 nm, for example, 2 nm to 80 nm, for example, 3 nm to 50 nm, for example, 4 nm to 40 nm or 5 nm to 30 nm.

In addition to the plurality of nanoparticles of sizes as discussed above, an oxide layer may comprise also smaller and/or larger nanoparticles.

The nanoparticles may have various shapes. At least some of them may be substantially elongate. At least some of them may be roughly cubic or roundish. The crystal structure of the oxide a nanoparticle is formed of may affect the three-dimensional shape thereof.

At least some of the plurality of nanoparticles 121 may be chemically bonded to the outer surface 111 of the substrate layer 110.

The illustrations of FIG. 1 are partial representations of the semiconductor structure 100 and its substrate layer 110 and oxide layer 120. This means that the semiconductor structure 100 with its layers may continue, in the horizontal directions outside the cut off part thereof shown in the illustrations of FIG. 1. On the other hand, a plurality of semiconductor substrates may be formed on, or belong to, a larger carrier such as a semiconductor wafer or a piece or die of such.

As mentioned above, “horizontal” refers, in the context of the FIGs., to the directions along or parallel to the fictitious base plane or surface along or parallel to which the substrate layer extends.

FIG. 2 shows a top view of the outer surface 111 of the substrate layer of the semiconductor structure of FIG. 1.

As illustrated in the drawing of FIG. 2, there are pore openings 112 with different shapes and sizes in the top part 111a part of the outer surface.

In various embodiments, the maximum diameter Dₚₒᵣₑ of the plurality of pore openings of different cavities may lie in the range of some tens to some hundreds of nanometers. There may be pore openings with maximum diameter Dₚₒᵣₑ of as low as 10 to 20 nm. On the other hand, there may be pore openings with maximum diameter Dₚₒᵣₑ of 100 to 200 nm. In some embodiments, pore openings with maximum diameter of more than 500 nm and even more than 1000 nm may be present.

In the case of an elongated cavity and pore opening, the maximum diameter Dₚₒᵣₑ may be relatively long, but the width of the pore opening may still be very narrow. It may be preferable that at least some of the plurality of cavities are dimensioned so that the pore openings they define can at least accommodate a circle C of a specific size. For example, each of the plurality of pore openings may have a size and shape capable of accommodating a circle C with a diameter of 5 nm, for example, with a diameter of 10 nm, 20 nm, or 50 nm.

A pore opening “accommodating” a circle with specific diameter refers to the shape and size of the pore opening being such that a fictitious circle of that specific size could fit in the pore opening. This means that the pore opening has at least one region where all the dimensions of the pore opening, thus also the “width” thereof, equals or is higher than the specific diameter.

Further, it has been found that at least in some embodiments, the plurality of cavities comprise a sufficient number of sufficiently large cavities defining sufficiently large pore openings. For example, such cavities may define pore openings having a size and shape capable of accommodating a circle with a diameter of 20 nm, for example, 40 nm, for example, 80 nm with an average density of at least 3 pores per μm², for example, 5 pores/μm², for example, at least 8 pores/μm². Thus, there may be, for example, pore openings having a size and shape capable of accommodating a circle with a diameter of 40 nm with an average density of at least 3 pores per μm² 5 pores/μm². Any other combination of those circle diameter and average density values is also possible.

FIG. 3 illustrates a SEM image of a porous outer surface 311 of a GaAs substrate layer 310 of a GaAs semiconductor substrate after an HHP exposure. The initially flat outer surface 311 was exposed to HHP of 80 °C for an HHP treatment period, i.e. length of the HHP treatment, of 150 minutes.

There are cavities 311b defining pore openings 312 of different sizes visible in the image. Some of the pore openings are elongated. The largest pores have maximum diameter of about 650 nm. There are many a bit smaller pore openings also, having their maximum diameter in the range of 200 to 500 nm. In addition, also substantially smaller pore openings with maximum diameter below 50 nm, even as low as 10 to 20 nm, are present.

FIG. 4 illustrates a SEM image of a semiconductor structure 400 with a GaAs substrate layer, the outer surface of which was first exposed to a HHP treatment similar to that of the sample of FIG. 3. Thereafter, the porous outer surface was exposed to HW of 80 °C for an HW treatment period, i.e. length of the HW treatment, of 150 minutes.

In result of the HW treatment, an oxide layer 420 comprising crystalline nanostructures was formed on all over the outer surface. The formation of the oxide layer of oxides of Ga and As was confirmed by energy dispersive spectroscopy EDS and X-ray photoelectron spectroscopy XPS measurements.

The SEM image of FIG. 4 shows the hazy appearance of the oxide layer 420, resulting from the oxide layer comprising a plurality of nanoparticles instead of being formed as a solid, single crystal layer.

The SEM image of FIG. 4 illustrates how the oxide layer 420 formed both on the top part and the cavities of the outer surface has filled the smallest cavities. The shapes of the largest cavities are still clearly visible. Despite the presence of the oxide layer on the outer surface, it can be seen in the image of FIG. 4. that there are some cavities in the outer surface defining pore openings with maximum diameter even exceeding 1 μm.

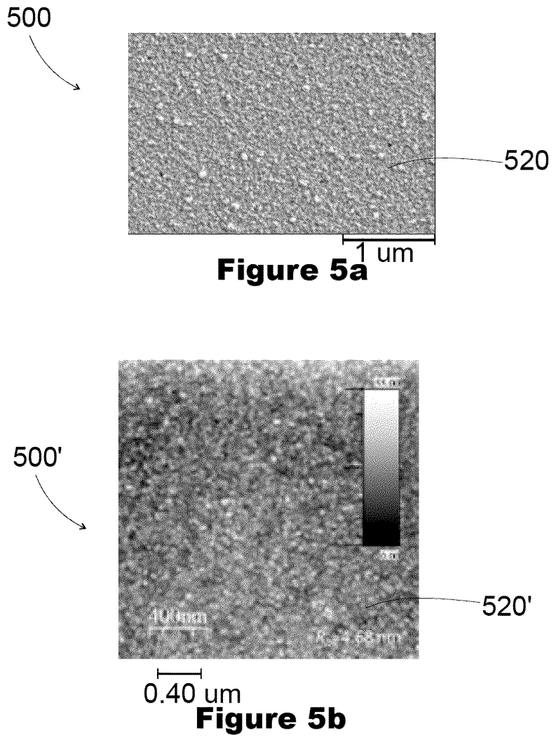

It shall be noted that the number or density, and the dimensions of the pores illustrated in FIGS. 1 to 4 may vary, depending, for example, on the HHP and/or HW treatment parameters such as the temperature and the duration of the treatment periods. The porosity of FIG. 1 is one example which may be the case, for example, for the compound semiconductor being GaAs. FIGS. 3 and 4 exemplify the porosity of the outer surface in the case of GaAs being the substrate material, and for the HHP and HW treatments parameters specified above. Deviation from those parameters may result in different porosity. It is even possible that there are substantially no pores formed, or that there are pores which are no longer observable by the resolution used, especially after formation of the oxide layer on the outer surface. One example of this is illustrated in FIG. 5.

FIG. 5a illustrates a SEM image of a semiconductor structure 500 with a GaSb substrate layer treated by HHP and HW. Before exposing the surface layer to HHP, the outer surface thereof was cleaned by subjecting it to a solution of hydrogen chloride, HCl, and isopropyl alcohol IPA, CH3CHOHCH3, with a ratio of (1:3); and then subjecting the outer sur-face to isopropyl alcohol IPA, CH3CHOHCH3. The durations of the first and second cleaning step were 3 and 1 minutes, respectively.

After cleaning, the outer surface of the GaSb substrate layer was first exposed to HHP of 80 °C for an HHP treatment period of 120 minutes. Thereafter, the outer surface was exposed to HW of 80 °C for an HW treatment period of 120 minutes.

After the treatments, an oxide layer 520 comprising crystalline nanostructures was formed on all over the outer surface. The formation of the oxide layer comprising oxides of Ga and Sb was confirmed by energy dispersive spectroscopy EDS and X-ray photoelectron spectroscopy XPS measurements.

FIG. 5b illustrates an AFM image of a semiconductor structure 500′ with a GaSb substrate layer treated by HHP and HW without pre-cleaning.

The outer surface of the GaSb substrate layer was first exposed to HHP of 80 °C for an HHP treatment period of 5 minutes. Thereafter, the outer surface was exposed to HW of 80 °C for an HW treatment period of 30 minutes.

After the treatments, an oxide layer 520′ comprising crystalline nanostructures was formed on all over the outer surface.

Similarly to the SEM image of the GaAs sample of FIG. 4, the SEM and AFM images of FIGS. 5a and 5b show the hazy or grainy appearance of the oxide layer 520, 520′ resulting from the oxide layer comprising a plurality of nanoparticles instead of being formed as a solid, single crystal layer.

No cavities or pores on the outer surface of the semiconductor substrate layer are seen in the SEM and AFM images of FIGS. 5a and 5b. This may be due to no cavities or pores being present, or cavities or pores being so small that they have been filled by the oxide layer.

It has been surprisingly found that III-V semiconductor structures in accordance with the above examples may possess advantageous optical performance, especially in terms of highly decreased reflectance in comparison to prior art III-V compound semiconductor layer surfaces. This enables the semiconductor structures discussed above to serve as anti-reflection structures, coatings, or layers.

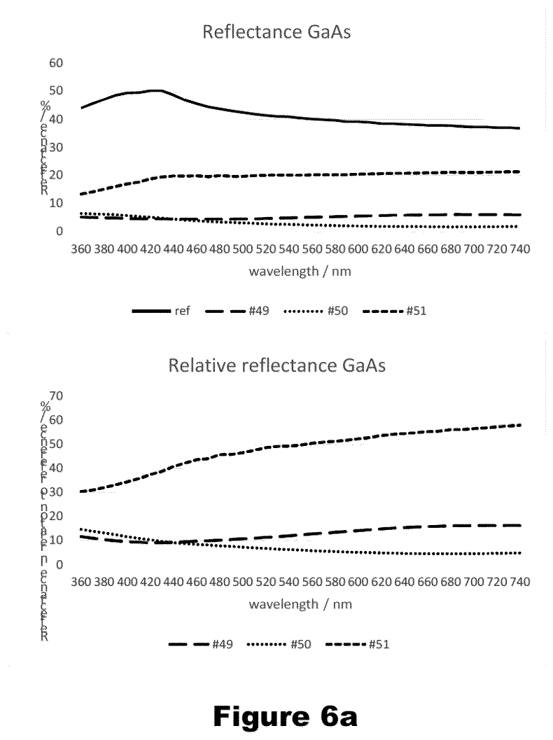

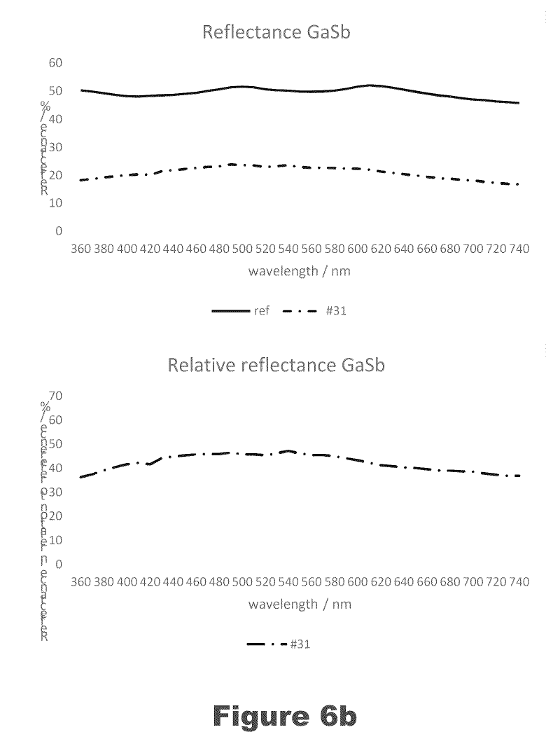

FIGS. 6a and 6b show results of reflectance measurements of three samples with a GaAs substrate layer, and one sample with a GaSb substrate layer, exposed to an HHP treatment, followed by an HW treatment. The GaAs samples were treated mutually differently. The treatment periods for the GaAs samples were as follows:

| Sample # | HHP 80 °C period | HW 80 °C period | |
|---|---|---|---|
| 49 | 150 min | 150 | min |
| 50 | 150 min | 30 | min |
| 51 | 150 min | 10 | min |

| | |
|---|---|
| 52 | Reference |

The outer surface of the GaSb substrate layer of the GaSb sample, denoted as sample #31, was treated by exposure to HHP at 80 °C for 5 minutes, followed by exposure to HW at 80 °C for 30 minutes. This was thus a treatment similar to that of the sample of FIG. 5b.

Reflectances of those samples and a reference GaAs or GaSb sample without any porous outer surface and/or an oxide layer thereon were measured with Konica Minolta CM-2300d handheld spectrometer using D65 illuminant and 10° observer.

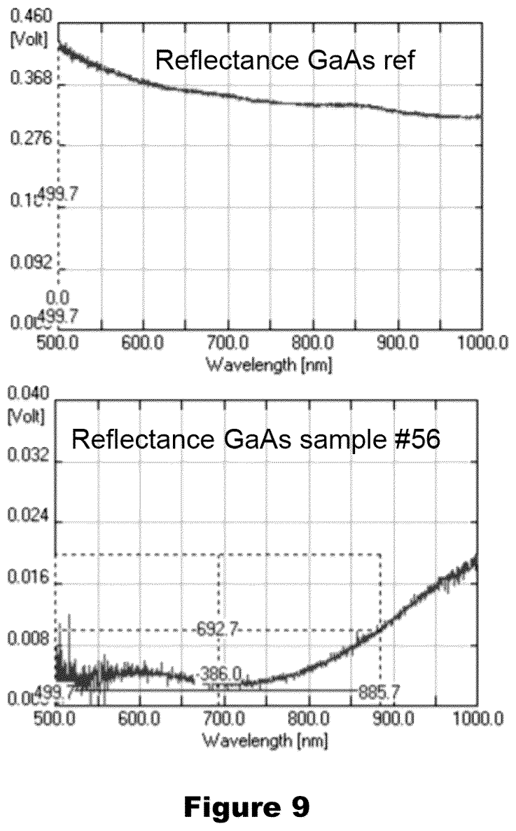

As the graphs of FIG. 6a show, each of the GaAs samples #49-51 showed a clear decrease of reflectance in comparison to the reference sample. For example, at wavelength of 425 nm, already the 10 min HW treatment after the 150 min HHP treatment resulted in more than 60% decrease in the reflectance. Longer HW treatment durations decrease the reflectance even by 90% and more, depending on the wavelength. For a GaAs sample treated by treatment periods of 240 min for both HHP and HW, reflectance of such low as less than 1% was measured. The result is shown in FIG. 9. The graphs of FIG. 9 show the voltage signal of the sensor detecting the reflected light for both a reference GaAs sample with no HHP or HW treatment, and the sample, denoted as “sample #56”, treated by exposure to HHP at 80 °C for 240 minutes, followed by exposure to HW at 80 °C for 240 minutes.

For the GaSb sample #31, the graphs of FIG. 6b show a decrease of reflectance of more than 50% in comparison to the reference GaSb sample.

As a specific advantage of the III-V semiconductor structures described above, the decrease of reflectance is broadband. In other words, reflectance is decreased over a broad wavelength range, actually over the entire wavelength band of 360 to 740 nm used in the measurements. As the curves indicate, highly lowered reflectance is expected also outside the visible spectrum, i.e. for ultraviolet UV and infrared IR wavelengths.

The broadband low reflectance was seen also visually as darkness or even blackness of the samples. The darkness may refer, for example, to dark blue or dark brown visual appearance of the treated sample. The reference GaAs and GaSb samples not subjected to HHP and HW treatments were grey.

In other embodiments, HHP and HW treatments may be carried out with temperature and the treatment duration differing from those examples discussed above. Examples are disclosed below with reference to FIG. 8.

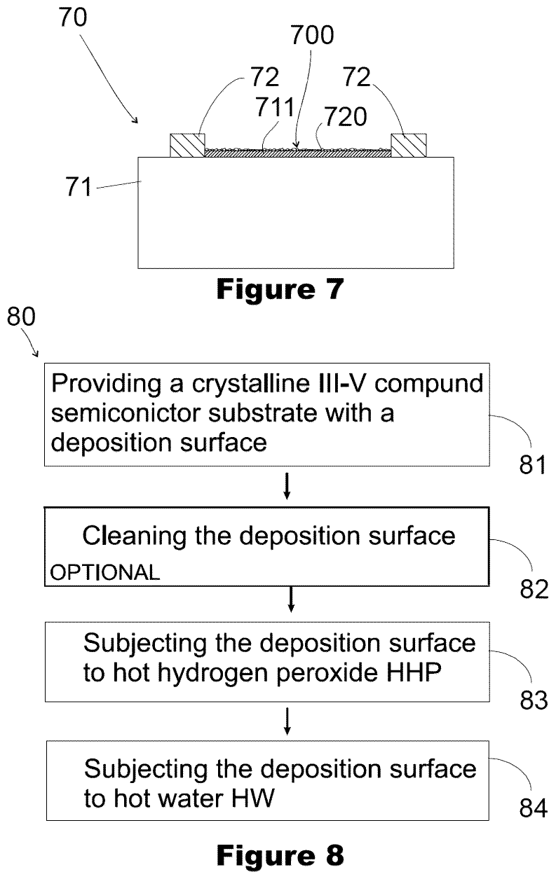

The cross-sectional image of FIG. 7 shows a III-V compound semiconductor device 70. This refers to a device, at least part of the operational device layer(s) of which are formed of a Ill-V compound semiconductor such as GaAs or InP.

The semiconductor device illustrated in a simplified and schematic form in the drawing of FIG. 7 may comprise any appropriate device layers, structures, and elements. In the drawing of FIG. 7, only a device layer part 71 denoting the device layer(s), contact structures 72, and a semiconductor structure 700 with a III-V compound semiconductor substrate layer 710 and an oxide layer 720 with nanoparticles thereon are illustrated. The semiconductor structure 700 may be in accordance with any of those discussed above with reference to FIGS. 1 to 6.

In the example of FIG. 7, the III-V compound semiconductor structure 700 is illustrated as an additional structure formed on the semiconductor device. In other embodiments, a III-V compound semiconductor structure may be formed in or on an existing structure of the semiconductor device. Then, any appropriate existing III-V compound semiconductor layer may serve as a substrate layer on which an oxide layer is formed.

The III-V compound semiconductor device 70 may be of any appropriate device type. Especially, it may be any of a solar cell, a photodetector, a light emitting diode LED, or a laser such as vertical-cavity sur-face-emitting laser, or any other light receiving and/or emitting device. Then, the III-V compound semiconductor structure may serve in the device as an anti-reflection structure, coating, or element. Thereby, it may improve light capture into, or light output out of, the III-V compound semiconductor device 70.

Any of those devices mentioned above may be designed and/or operate with one or more of the ultraviolet UV, visible, or infrared IR parts of the electromagnetic spectrum. In other words, for example, a LED or a photodetector may be a UV LED or a photodetector, a visible light LED or a photodetector, or an infrared LED or a photodetector. Visible part of the electromagnetic spectrum may refer, for example, to the wavelengths of about 340 nm to 780 nm, 380 nm to 750 nm, or 380 to 700 nm, or any other appropriate visible wavelength band commonly known in the art.

In addition to the light receiving/emitting device type examples mentioned above, a semiconductor structure in accordance with any of those discussed above with reference to FIGS. 1 to 7 may be incorporated in any appropriate other type of semiconductor device. Then, the semiconductor structure may serve for anti-reflection or for some other purposes.

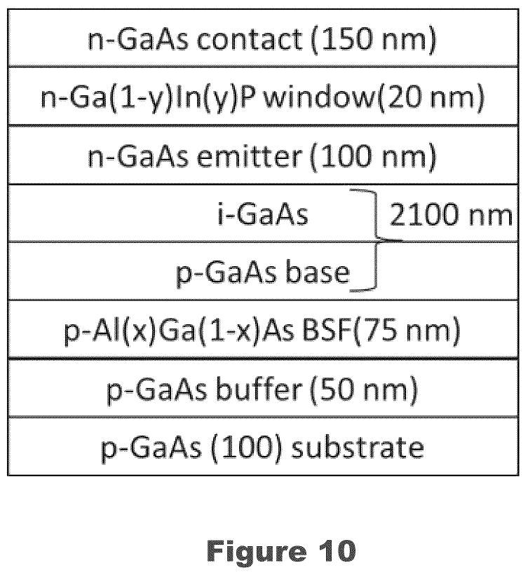

The semiconductor device of FIG. 10 is a GaAs based solar cell structure. It comprises a plurality of layers, part of which are n-type or p-type doped. The uppermost layer is a n-type GaAs contact layer. This layer was exposed to a HHP treatment at 80 °C for 30 minutes, and thereafter to a HW treatment at 80 °C for 30 minutes.

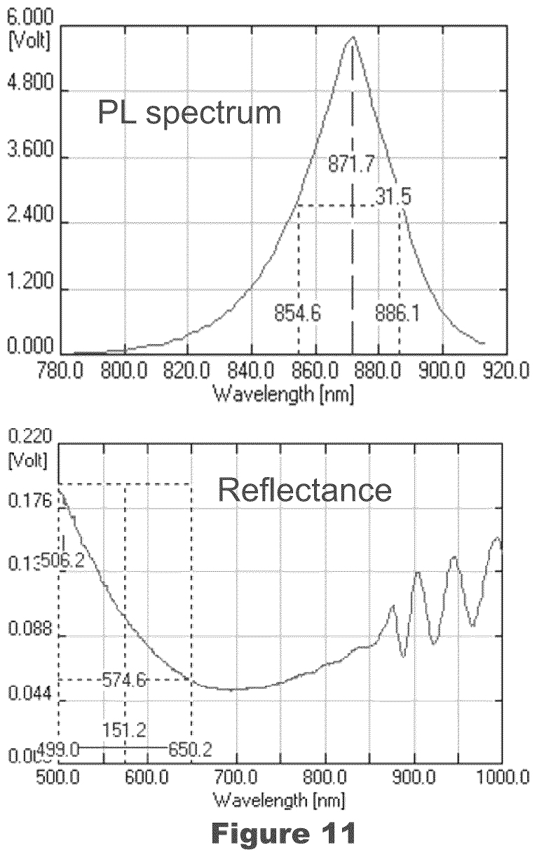

After the HHP+HW treatment, PL intensity measured from the GaAs contact layer was clearly increased in comparison to a identical reference solar cell structure not exposed to HHP or HW. On the other hand, reflectance measured from the same contact layer was highly reduced in comparison to the reflectance of the reference solar cell structure. The measured photoluminescence and reflectance spectra are shown in FIG. 11.

Above, mainly structural and material features of III-V compound semiconductor structures and semiconductor devices are discussed. In the following, more emphasis will lie on methods for forming III-V compound semiconductor structures. The III-V semiconductor structures discussed above may be formed by methods discussed hereinafter. Respectively, the methods hereinafter discussed may be used to manufacture III-V semiconductor structures in accordance with those discussed above.

The method 80 of FIG. 8 starts, in first operation 81, by providing a crystalline III-V compound semiconductor substrate having an outer surface. The group III element may comprise gallium, Ga, and/or indium, In, or antimony, Sb, and the group V element is arsenide, As, or phosphorus, P, respectively.

An “operation” may refer to a single action, or it may comprise a series of sub-operations or steps.

As discussed above with reference to FIGS. 1 to 7, the semiconductor substrate may be a stand-alone structure. Alternatively, it may be attached to another semiconductor structure such as a III-V compound semiconductor device, or form an integral, inseparable part of such device.

In second operation 82, the outer surface is cleaned. This may be carried out, for example, by subjecting the outer surface to a solution of hydrogen chloride, HCl, and isopropyl alcohol, CH₃CHOHCH₃, with a ratio of (1:3); and then subjecting the outer surface to isopropyl alcohol, CH₃CHOHCH₃. Duration of one or both of the subjection steps may be, for example, 1 to 5 minutes, for example, about 3 minutes.

In other embodiments, different cleaning operation(s) may be carried out. In yet other embodiments, methods without cleaning operation may be implemented, as indicated by the operation 82 being marked as optional in FIG. 8. For example, in some embodiments, a pre-cleaned semiconductor substrate may be used.

In third operation 83, the outer surface is subjected to liquid hot hydrogen peroxide HHP, H₂O₂, at a temperature of the HHP in the range of 60 °C to 99 °C, for example, 65 °C to 95 °C, for example, 70 °C to 90 °C, for example, about 80 °C. The HHP treatment period may have a duration of 2 minutes, at least 5 minutes, at least 10 minutes, at least 15 minutes, at least 30 minutes, or at least 60 minutes. Basically, there is no upper limit for the duration, but the effects resulted during the HHP treatment may be saturated after a certain duration of the treatment. Such saturation may take place, for example, for a substrate comprising GaAs or GaSb, after about 50, 100, 150, or 200 minutes. So, it may be advantageous at least from the production efficiency point of view to limit the duration to 50, 100, 150, or 200 minutes. For a substrate comprising GaAs or GaSb, saturation may also take place after about 240 or 250 minutes.

As discussed above with reference to FIGS. 1 to 7, the HHP treatment may result in the outer surface becoming porous.

The possibly porous outer surface is then subjected, in fourth operation 84, to liquid hot water HW, H₂O, at a temperature of the HW in the range of 60 °C to 99 °C, for example, 65 °C to 95 °C, for example, 70 °C to 90 °C, for example, about 80 °C. The HW treatment period may have a duration of at least 2 minutes, at least 5 minutes, at least 10 minutes, at least 15 minutes, at least 30 minutes, or at least 60 minutes. Basically, there is no upper limit for the duration, but the effects resulted during the HW treatment may be saturated after a certain duration of the treatment. Such saturation may take place, for example, for a substrate comprising GaAs or GaSb, after about 50, 100, 150, 200, or 240 minutes. So, it may be advantageous from the production efficiency point of view to limit the duration to 50, 100, 150, 200, or 240 or 250 minutes.

Water used in the HW treatment may be deionized water. In other embodiments, it may be distilled water. It may also be possible to use regular water, such as tap water, without any further treatment needed to be applied to the water. Further, in some embodiments, heavy water may be used.

As discussed above with reference to FIGS. 1 to 7, the HW treatment results in an oxide layer being formed on the outer surface. Then, the III-V semiconductor substrate may become visually black, dark blue, or dark brown, having reduced reflectance in the visible wavelength band.

An HHP or HW treatment period refers to the time the deposition is subjected to HHP or HW, respectively. As specified above, the durations of that time period may vary.

For the HHP treatment for a GaAs substrate, it has been found that a porous outer surface may be produced already by an HHP treatment period of 5 or 10 minutes. With longer periods, more and larger cavities may be formed on the outer surface. Larger pores may result from combination of a plurality of smaller ones.

For the HW treatment, it has been found that an oxide layer covering the porous outer surface may be produced already by an HW treatment period of 5 or 10 minutes. With longer periods, more oxide of the III and V elements may be formed, and/or more or larger nanoparticles may be formed.

The method may be carried out with any appropriate combination of the HHP and HW treatment period durations. For example, for a GaSb substrate, an AR structure may be produced already with durations of 5 and 30 minutes of the HHP and HW treatment periods, respectively.

Tests have shown that high blackness or darkness, i.e. highly reduced reflectance over a broad wavelength range may be achieved, for example, for a GaAs substrate, with the following durations of the HHP and HW treatments: HHP 30 min and HW 30 min; HHP 150 min and HW 10 min; HHP 150 min and HW 30 min; or and HHP 150 min and HW 150 min.

For a GaSb substrate, highly reduced reflectance over a broad wavelength range may be achieved, for example, with the following durations of the HHP and HW treatment periods: HHP 5 min and HW 30 min. Another example found to be workable was: HHP 120 min and HW 120 min.

“Subjecting” the outer surface to HHP or HP refers to treating the outer surface by HHP, or HP, respectively. Then, the outer surface is arranged into contact with liquid HHP or HW so that physical and/or chemical interaction between the outer surface and HHP or HW is possible.

Said arranging may be carried out in any appropriate manner, using any appropriate means. For example, a beaker containing liquid HHP or HW may be used. Then, the outer surface of the semiconductor structure may be simply dipped into the liquid HHP or HW contained in the beaker. A large number of semiconductor structures may be formed, for example, on a single wafer. Then, dipping the wafer to the beaker enables AR semiconductor structures to be produced by an efficient batch process. Thereby, the method may be scaled for industrial purposes.

Various embodiments of the method may advantageously provide an efficient, simple, and low-cost way to produce III-V compound semiconductor structures suitable for serving as antireflection AR structures.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

1. A III-V compound semiconductor structure (100) for serving as an anti-reflection structure, comprising:
a crystalline III-V compound semiconductor substrate layer (110), wherein the group III element comprises gallium Ga, and/or indium In, and the group V element is arsenide As, phosphorus P, or antimony Sb;
the substrate layer (110) having an outer surface (111); and
an oxide layer (120) of oxide(s) of the III-V semiconductor substrate layer on the outer surface, the oxide layer comprising a plurality of crystalline nanoparticles (121) having a maximum diameter in the range of 0.2 nm to 200 nm, for example, 0.5 nm to 150 nm, for example, 1 nm to 100 nm, for example, 2 nm to 80 nm, for example, 3 nm to 50 nm.

2. A III-V compound semiconductor structure (100) as defined in claim 1, wherein the outer surface is porous, and has a top part (111a) and a plurality of cavities (111b) extending from the level of the top part into the substrate layer, the cross-section of a cavity at the level of the top part defining a sub-micron pore opening (112).

3. A III-V compound semiconductor structure (100) as defined in claim 2, wherein the substrate layer comprises gallium arsenide GaAs.

4. A III-V compound semiconductor structure (100) as defined in claim 2, wherein each of the plurality of pore openings (112) has a size and shape capable of accommodating a circle with a diameter of 5 nm, for example, a circle with a diameter of 10, 20, or 50 nm.

5. A III-V compound semiconductor structure (100) as defined in claim 4, wherein the plurality of pore openings (112) comprises pore openings having a size and shape capable of accommodating a circle with a diameter of 20 nm, for example, 40 nm, for example, 80 nm with an average density of at least 3 pores per μm², for example, at least 5 pores/μm², for example, at least 8 pores/μm².

6. A III-V compound semiconductor structure (100) as defined in claim 1, wherein the oxide layer (120) has a thickness of 0.2 nm to 400 nm or 0.2 to 200 nm, for example, 0.5 nm to 150 nm, for example, 1 nm to 100 nm, for example, 2 nm to 80 nm, for example, 3 nm to 50 nm, for example, 4 nm to 40 nm or 5 nm to 30 nm.

7. A III-V compound semiconductor structure (100) as defined in claim 1, wherein the III-V compound semiconductor is GaAs, InGaAs, or GaSb, and the oxide layer (120) comprises gallium oxide GaOₓ.

8. A III-V compound semiconductor structure (100) as defined in claim 1, wherein the oxide layer (120) comprises oxide hydroxide of the group III element.

9. A III-V compound semiconductor structure (100) as defined in claim 1, wherein the plurality of nanoparticles (121) are chemically bonded to the outer surface (111a, 111b).

10. A III-V compound semiconductor structure (100) as defined in claim 1, wherein the semiconductor structure is obtainable by a method according to claim 13.

11. A semiconductor device (60) comprising a III-V compound semiconductor structure (600) as defined in claim 1, wherein the semiconductor structure forms an antireflection AR structure.

12. A semiconductor device (60) as defined in claim 9, wherein the semiconductor device is a solar cell, a photodetector, a light emitting diose LED, or a laser, such as a vertical-cavity surface-emitting laser.

13. A method (70) for forming a III-V compound semiconductor structure for serving as an anti-reflection structure, the method comprising:
providing a crystalline III-V compound semiconductor substrate layer, wherein the group III element comprises gallium Ga and/or indium In, and the group V element is arsenide As, phosphorus P, or antimony Sb, the substrate layer having an outer surface (71);
subjecting the outer surface to liquid hot hydrogen peroxide H₂O₂, HHP, at a temperature of the HHP in the range of 60 °C to 99 °C, for example, 65 °C to 95 °C, for example, 70 °C to 90 °C, for example, about 80 °C, for an HHP treatment period of at least 2 minutes, at least 5 minutes, at least 10 minutes, at least 15 minutes, at least 30 minutes, or at least 60 minutes (73); and
then subjecting the outer surface to liquid hot water H₂O, HW, at a temperature of the HW in the range of 60 °C to 99 °C, for example, 65 °C to 95 °C, for example, 70 °C to 90 °C, for example, about 80 °C, for an HW treatment period of at least 2 minutes, at least 5 minutes, at least 10 minutes, at least 15 minutes, at least 30 minutes, or at least 60 minutes (74).

14. A method (70) as defined in claim 13, wherein the duration of the HHP treatment period and/or the HW treatment period is less than or equal to 250 minutes, for example, less than or equal to 200 minutes, for example, less than or equal to 150 minutes, for example, less than or equal to 100 minutes, for example, less than or equal to 50 minutes.

15. A method (70) as defined in claim 13, wherein the duration of both of the HHP treatment (73) period and the HW treatment (74) period is about 30 minutes.

16. A method (70) as defined in claim 13, wherein the duration of both of the HHP treatment (73) period and the HW treatment period (74) is about 150 minutes.

17. A method (70) as defined in claim 13, wherein the semiconductor substrate layer comprises gallium antimony GaSb, and the duration of the HHP treatment period is about 5 minutes, and the duration of the HW treatment period is about 30 minutes.

18. A method (70) as defined in claim 13, wherein the water is deionized water or distilled water.

19. A method (70) as defined in claim 13, wherein before the subjection to HHP, the method comprises cleaning the outer surface (72).

20. A method (70) as defined in claim 19, wherein the cleaning comprises:
subjecting the outer surface to a solution of hydrogen chloride HCl, and isopropyl alcohol CH₃CHOHCH₃, with a ratio of (1:3); and
then subjecting the outer surface to isopropyl alcohol CH₃CHOHCH₃.
